(19) United States
(12) Patent Application Publication
(10) Pub. No.: US 2025/0084534 A1
(43) Pub. Date: Mar. 13, 2025

(54) METHOD OF DEPOSITING EPITAXIAL MATERIAL, STRUCTURE FORMED USING THE METHOD, AND SYSTEM FOR PERFORMING THE METHOD

(71) Applicant: ASM IP Holding B.V., Almere (NL)

(72) Inventors: Amir Kajbafvala, Chandler, AZ (US); Caleb Miskin, Mesa, AZ (US)

(21) Appl. No.: 18/961,650

(22) Filed: Nov. 27, 2024

Related U.S. Application Data
(63) Continuation of application No. 17/184,290, filed on Feb. 24, 2021, now Pat. No. 12,173,404.
(60) Provisional application No. 62/990,807, filed on Mar. 17, 2020.

(51) Int. Cl. C23C 16/455; C23C 16/24; C23C 16/42; C23C 16/44; C23C 16/52; C23C 16/56; H01L 21/02

(52) U.S. Cl. CPC C23C 16/45557; C23C 16/24; C23C 16/42; C23C 16/4404; C23C 16/45553; C23C 16/52; C23C 16/56; H01L 21/02381; H01L 21/02532; H01L 21/0262

(57) ABSTRACT

A method of depositing one or more epitaxial material layers, a device structure formed using the method and a system for performing the method are disclosed. Exemplary methods include coating a surface of a reaction chamber with a precoat material, processing a number of substrates, and then cleaning the reaction chamber.

### CROSS-REFERENCE TO RELATED APPLICATIONS

This application is a continuation of, and claims priority to and the benefit of, U.S. patent application Ser. No. 17/184,290, filed Feb. 24, 2021 and entitled “METHOD OF DEPOSITING EPITAXIAL MATERIAL, STRUCTURE FORMED USING THE METHOD, AND SYSTEM FOR PERFORMING THE METHOD,” which is a nonprovisional of, and claims priority to and the benefit of, U.S. Provisional Patent Application No. 62/990,807, filed Mar. 17, 2020 and entitled “METHOD OF DEPOSITING EPITAXIAL MATERIAL, STRUCTURE FORMED USING THE METHOD, AND SYSTEM FOR PERFORMING THE METHOD,” both of which are hereby incorporated by reference herein.

### FIELD OF THE DISCLOSURE

The present disclosure generally relates to gas-phase reactors and systems and to methods of using the reactors and systems. More particularly, the disclosure relates to methods of depositing epitaxial material, to systems for depositing the epitaxial material, and to structures formed using the methods and systems.

### BACKGROUND OF THE DISCLOSURE

Gas-phase reactors, such as chemical vapor deposition (CVD) reactors, can be used for a variety of applications, including depositing and etching materials on a substrate surface. For example, gas-phase reactors can be used to deposit epitaxial layers on a substrate to form semiconductor devices, flat panel display devices, photovoltaic devices, microelectromechanical systems (MEMS), and the like.

A typical gas-phase epitaxial reactor system includes a reactor including a reaction chamber, one or more precursor and/or reactant gas sources fluidly coupled to the reaction chamber, one or more carrier and/or purge gas sources fluidly coupled to the reaction chamber, a gas injection system to deliver gases (e.g., precursor/reactant gas(es) and/or carrier/purge gas(es)) to the reaction chamber, a susceptor to retain and heat a substrate, and an exhaust source fluidly coupled to the reaction chamber. Further, epitaxial reactor systems can include one or more heaters (e.g., lamps) and/or temperature measurement devices (e.g., pyrometers) that are exterior to the reaction chamber. The lamps can be used to heat areas within the reaction chamber. The pyrometers can be used to measure the temperature within the reaction chamber (e.g., of the susceptor and/or of a reaction chamber wall).

During an epitaxial deposition process, a layer of epitaxial material is deposited onto or grows on a surface of a substrate. In addition, material can be deposited onto walls of the reaction chamber, the susceptor, and the like within the reaction chamber. The material that deposits on the walls of the reaction chamber and the susceptor can affect a thermal and/or chemical environment within the reaction chamber, which, in turn, can affect deposition (e.g., rate and/or uniformity) of material that is subsequently deposited onto a surface of a substrate. Further, once material deposits onto the walls of the reaction chamber and/or susceptor, the material can be difficult to remove. Therefore, the reaction chamber is cleaned after each substrate or deposition process to remove residue from an interior of the reaction chamber.

Although such processes work well for some applications, cleaning the interior of the reaction chamber after each process run is time consuming and expensive. Furthermore, as sizes of features formed on a substrate surface decrease, it becomes increasingly important to control film properties, such as film thickness and resistivity. Accordingly, improved systems and methods for depositing epitaxial materials on a surface of a substrate are desired.

### SUMMARY OF THE DISCLOSURE

Various embodiments of the present disclosure relate to improved methods and systems for depositing epitaxial material on a surface of a substrate and to structures formed using the methods and systems. While the ways in which various embodiments of the present disclosure address drawbacks of prior systems and methods are discussed in more detail below, in general, various embodiments of the disclosure provide methods and systems that can be used to deposit epitaxial material in a time- and/or cost-effective manner. Exemplary methods can be used to process multiple substrates and/or perform multiple processes without cleaning an interior of a reaction chamber, while maintaining or even improving within substrate and/or substrate-to-substrate uniformity of film thickness, composition, and/or the like.

In accordance with exemplary embodiments of the disclosure, a method of depositing an epitaxial material layer is provided. The method can be used to form a plurality of epitaxial material layers on a surface of a substrate. Exemplary methods include coating a surface of a reaction chamber with a precoat material, providing a substrate within a reaction chamber of a reactor system (e.g., after the step of coating), depositing one or more epitaxial material layers on a surface of the substrate; and repeating the steps of providing a substrate within a reaction chamber and depositing an epitaxial material layer on the surface of the substrate prior to a step of cleaning the reaction chamber. Exemplary methods can further include the step of cleaning the reaction chamber. Exemplary precoat material includes silicon. The precoat material can include additional elements, such as germanium. In accordance with examples of the disclosure, the precoat material includes greater than 70 atomic percent silicon. In accordance with further examples of the disclosure, a precursor including a halogen is provided to the reaction chamber. Additionally or alternatively, an etchant is provided to the reaction chamber during the step of depositing the epitaxial material layer and/or the step of coating a surface of a reaction chamber with a precoat material. The etchant can include, for example, a halogen. The step of providing a substrate within a reaction chamber can be repeated three or more times, five or more times, or 10, 15, 25 or more times, prior to the step of cleaning the reaction chamber. Thus, throughput of the method can be relatively high, compared to traditional epitaxial deposition methods and/or costs associated with depositing epitaxial material on substrates can be relatively low, compared to costs associated with depositing epitaxial material using traditional methods.

In accordance with further examples of the disclosure, temperatures of two or more temperature zones within the reaction chamber can be controlled. The temperature can be controlled, for example, during one or more of the steps of coating a surface of a reaction chamber with a precoat material and depositing an epitaxial material layer on a surface of the substrate. Using multiple temperature zones to control a temperature within a reaction chamber can further facilitate control of film thickness, composition, other properties, and uniformity thereof, of material deposited during the step of depositing an epitaxial material layer on a surface of the substrate.

In accordance with additional exemplary embodiments of the disclosure, a method of forming a device structure is provided. Exemplary device structures can include, for example, silicon, silicon germanium, or one or more layers comprising silicon and one or more layers comprising silicon germanium. By way of examples, the device structure can be used to form a field effect transistor, such as a gate all around device.

In accordance with yet additional exemplary embodiments of the disclosure, a system for performing a method and/or for forming a device structure is provided.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with at least one exemplary embodiment of the present disclosure.

FIG. 2 schematically illustrates a device structure formed in accordance with at least one exemplary embodiment of the disclosure.

FIG. 3 schematically illustrates another device structure formed in accordance with at least one exemplary embodiment of the disclosure.

FIG. 4 schematically illustrates a reactor system in accordance with at least one exemplary embodiment of the disclosure.

FIG. 5 illustrates another reactor system in accordance with examples of the disclosure.

FIG. 6 illustrates another device structure formed in accordance with at least one exemplary embodiment of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

The present disclosure generally relates to methods and systems for depositing epitaxial material. Exemplary methods and systems can be used to process substrates, such as semiconductor wafers, during the manufacture of devices, such as semiconductor devices, flat panel display devices, photovoltaic devices, microelectromechanical systems (MEMS), and the like. By way of examples, exemplary systems and methods described herein can be used to form or grow epitaxial layers (e.g., one component, two component and/or doped semiconductor layers) on a surface of a substrate. Exemplary systems can further be used to provide clean interior surfaces of the reaction chamber after a number (e.g., greater than 2, 3, 5, 10, 15, 25, or the like) of process or substrate runs.

As used herein, the terms “precursor” and/or “reactant” can refer to one or more gases/vapors that take part in a chemical reaction or from which a gas-phase substance that takes part in a reaction is derived. The chemical reaction can take place in the gas phase and/or between a gas phase and a surface (e.g., of a substrate or reaction chamber) and/or a species on a surface (e.g., of a substrate or a reaction chamber).

As used herein, a “substrate” refers to any material having a surface onto which material can be deposited. A substrate may include a bulk material such as a Group IV (e.g., silicon, such as single crystal silicon) or other semiconductor material, such as Group III-V or Group II-VI semiconductor material, or may include one or more layers overlying the bulk material. Further, the substrate may include various topologies, such as trenches, vias, lines, and the like formed within or on at least a portion of a layer of the substrate. In accordance with examples of the disclosure, a substrate includes a surface that includes crystalline semiconductor material.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

The term “inert gas” can refer to a gas that does not take part in a chemical reaction and/or does not become a part of a film matrix to an appreciable extent. Exemplary inert gases include helium, argon, and any combination thereof. A carrier can be or include an inert gas. A dilution gas can be or include an inert gas or hydrogen.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying the substrate, such as one or more layers formed according to a method as described herein. Device portions can be or include structures.

As used herein, the term “epitaxial layer” can refer to a substantially single crystalline layer upon an underlying substantially single crystalline substrate or layer.

As used herein, the term “chemical vapor deposition” can refer to any process wherein a substrate is exposed to one or more gas-phase precursors, which react and/or decompose on a substrate surface to produce a desired deposition.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

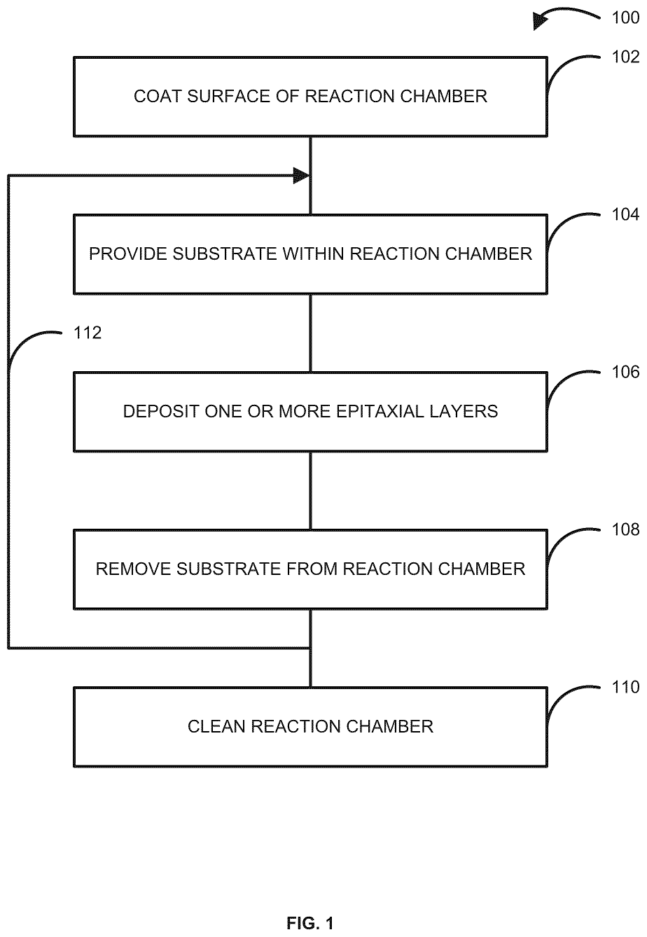

Turning now to the figures, FIG. 1 illustrates an exemplary method 100 in accordance with examples of the disclosure. Method 100 can be used to deposit an epitaxial material layer—e.g., during formation of a device structure.

In the illustrated example, method 100 includes coating a surface of a reaction chamber (step 102), providing a substrate within a reaction chamber (step 104), depositing one or more epitaxial material layers on a surface of the substrate (step 106), removing the substrate from the reaction chamber (step 108), cleaning the reaction chamber (step 110), and repeating steps 104-108 for additional substrates (loop 112).

During step 102, a precoat material is deposited onto a surface within a reaction chamber. The surfaces can include, for example, surfaces of a wall or walls of the reaction chamber, a surface or surfaces of a susceptor, surfaces of various inlets to or outlets from the reaction chamber, and the like. By way of examples, the surface within the reaction chamber includes at least a top surface of a susceptor.

To deposit the precoat material, one or more precursors and/or reactants are provided to the reaction chamber. The precursors can desirably include at least one element in common with the epitaxial material to be deposited. For example, when the epitaxial material to be deposited onto the substrate includes silicon, at least one of the precursors can include silicon. Further, when the epitaxial material to be deposited onto the substrate includes germanium, at least one of the precursors can include germanium.

Exemplary precursors for use during step 102 include halides, such as silicon halides. In some embodiments, the silicon halide compound can include, for example, a silicon halide having the general formula given as: SiₓW_{y}H₂, wherein “W” is a halide selected from the group consisting of Fluorine (F), Chlorine (Cl), Bromine (Br), and Iodine (I), “x” and “y” are integers greater than zero, and “z” is an integer greater than or equal to zero. In some embodiments, the silicon halide precursor may be selected from the group consisting of silicon fluorides (e.g., SiF₄), silicon chlorides (e.g., SiCl₄), silicon bromides (e.g., SiBr₄), and silicon iodides (e.g., Sil₄). In some embodiments, the silicon halide precursor may comprise silicon tetrachloride (SiCl₄).

In some embodiments, precursor may comprise a silane, such as, for example, silane (SiH₄), disilane (Si₂H₆), trisilane (Si₃H₈), tetrasilane (Si₄H₁₀) or higher order silanes with the general empirical formula SiₓH₍₂ₓ₊₂₎.

By way of examples, the precursor can be or include one or more of silicon tetrachloride (SiCl₄), trichloro-silane (SiCl₃H), dichlorosilane (SiCl₂H₂), monochlorosilane (SiClH₃), hexachlorodisilane (HCDS), octachlorotrisilane (OCTS), a silicon iodide, a silicon bromide; or an amino-based precursor, such as hexakis(ethylamino)disilane (AHEAD) and SiH[N(CH₃)₂]₃(3DMASi), a bis(dialkylamino) silane, such as BDEAS (bis(diethylamino)silane); a mono(alkylamino)silane, such as di-isopropylaminosilane; or an oxysilane based precursor, such as tetraethoxysilane Si(OC₂H₅)₄.

In some cases, the precursor preferentially includes a halogen. It is thought that precursors including a halogen may preferentially cause deposition on a susceptor, relative to deposition on a reaction chamber, which may provide for better deposition uniformity of subsequently deposited epitaxial layers on a substrate surface.

In some cases, a dilution gas, such as hydrogen, or an inert gas can be provided to the reaction chamber during step 102. Additionally or alternatively, a carrier gas, such as an inert gas, can be provided to the reaction chamber during step 102.

In accordance with further examples of the disclosure, an etchant can be provided to the reaction chamber during step 102. The etchant can be provided from the same source vessel as the precursor or separately provided to the reaction chamber.

Exemplary etchants include halides, such as compounds comprising one or more of fluorine (F), chlorine (Cl), bromine (Br), and iodine (I). By way of examples, the etchant can be or include hydrogen chloride and/or one or more halogen gases, such as F₂, Cl₂, Br₂, and I₂. Similar to use of a precursor including a halogen, use of an etchant is thought to cause higher deposition on a susceptor during step 102, relative to a reaction chamber wall, which may provide for better deposition uniformity of subsequently deposited epitaxial layers on a substrate surface.

During step 102, a temperature within the reaction chamber (e.g., of a susceptor and/or reaction chamber wall) can be about 850° C. to about 1050° C., about 850° C. to about 950° C., or about 900° C. to about 950° C. A pressure within the reaction chamber can be about 10 Torr to about 1 ATM, about 10 to about 500 Torr, or about 15 Torr to about 200 Torr. A flowrate of the precursor to the reaction chamber can be about 50 sccm to about 1000 sccm, about 100 sccm to about 900 sccm, or about 200 sccm to about 700 sccm.

A thickness of material deposited during step 102 can vary according to various factors. By way of examples, when the epitaxial material comprises silicon, a thickness of the layer of material on the susceptor can be about 50 to about 5000 Angstroms, about 50 to about 2000 Angstroms, or about 0.5 to about 20 microns. When the epitaxial material comprises germanium (e.g., silicon germanium), a thickness of the layer of material on the susceptor can be about 10 to about 5000 Angstroms, about 10 to about 1000 Angstroms, about 10 to about 500 Angstroms, about 0.5 microns to about 10 microns, or about 0.5 microns to about 20 microns.

During step 104, one or more substrates are loaded into the reaction chamber. During this step, the temperature of the reaction chamber (e.g., of a susceptor and/or reaction chamber wall) may decrease to about 200° C. to about 900° C., about 200° C. to about 700° C., about 500° C. to about 900° C., or about 500° C. to about 650° C. A pressure within the reaction chamber can be about 10 Torr to about 80 Torr, about 10 Torr to about 200 Torr, or about 5 Torr to about 600 Torr.

Once a substrate is loaded into the reaction chamber, the reaction chamber can be brought to a desired temperature and pressure for step 106 of depositing one or more epitaxial layers. The temperature within the reaction chamber during steps 104 and/or 106 can be lower than a temperature within the reaction chamber during step 102.

In some cases, method 100 can include a bake step prior to step 106. In these cases, a temperature within the reaction chamber can be about 600° C. to about 1200° C., about 650° C. to about 1000° C., or about 700° C. to about 900° C. during the bake step. A pressure within the reaction chamber during the bake step can be about 2 Torr to about 1 ATM, about 2 Torr to about 400 Torr, or 2 Torr to about 200 Torr. After step 104 and any bake step, the reaction chamber (e.g., a susceptor within the reaction chamber) can be brought to a desired deposition temperature.

During step 106, one or more epitaxial layers are deposited onto a surface of a substrate. The precursors used to deposit the epitaxial material can include a semiconductor material, such as a Group IV, Group III-V, and/or Group II-VI semiconductor material. By way of illustrative examples, the precursor and the epitaxial material can include silicon.

Suitable silicon precursors for depositing epitaxial silicon include any of the silicon precursors noted above. By way of examples, dichlorosilane (DCS), silane (SiH₄), and/or disilane (SI₂H₆) can be used as a reactant.

Suitable germanium precursors for deposition of an epitaxial layer comprising germanium (e.g., germanium or silicon germanium layers) include germane, digermane, and the like.

The deposition temperature can be about 350° C. to about 950° C., about 350° C. to about 800° C., or about 600° C. to about 800° C. A pressure within the reaction chamber during the bake step can be about 2 Torr to about 1 ATM, about 2 Torr to about 400 Torr, or about 2Torr to about 200 Torr. A flowrate of a silicon precursor can be about 10 sccm to about 700 sccm, or 10 sccm to about 300 sccm; flowrate of a germanium precursor can be about 10 sccm to about 990 sccm, about 10 sccm to about 220 sccm, or about 10 sccm to about 85 sccm; either or which flowrates can be with or without a carrier gas.

In accordance with examples of the disclosure, one or more (e.g., alternating) layers of silicon and/or silicon germanium (e.g., a single layer of silicon germanium) can be deposited during step 106. In accordance with these examples, the silicon can be, for example, intrinsically doped or include a dopant, such as germanium, boron, arsenic, phosphorous in a concentration of about 1 to about 40 atomic percent. The silicon germanium layer can include from greater than 60 at % silicon, greater than 90 at % silicon, or about 18 to about 35 or about 20 to about 30 atomic percent germanium and about 70 to about 80 or about 65 to about 80 atomic percent silicon.

A number of epitaxial material layers can vary. In accordance with examples of the disclosure, about 1 to about 8, or about 1 to about 6 or about 1 to 4 or about 1 to 3 silicon epitaxial material layers alternating with about 0 to about 8, or about 0 to about 6, or about 0 to 4, silicon germanium epitaxial material layers can be deposited onto the substrate surface during step 106.

In accordance with other examples of the disclosure, the one or more layers can include a single layer of silicon germanium. Such layers can be used to, for example, form a channel region of a field effect transistor.

During step 108, the one or more substrates are removed from the reaction chamber. During this step, the reaction chamber may be allowed to cool—e.g., to a temperature of about 550 to about 650 or about 500 to about 800 and brought to a desired pressure for substrate transfer.

Once the substrate(s) are removed from the reaction chamber, steps 104-108 can be repeated a number of times. For example, loop 112 can be repeated 1, 2, 3, 4, 5, 6, 8, 10, 12, 15, 25, 50, 75 or more times prior to method 100 proceeding to step 110.

During step 110, the reaction chamber is cleaned using an etchant to remove material deposited during steps 102 and 106. Exemplary etchants include halides, such as compounds comprising one or more of fluorine (F), chlorine (Cl), bromine (Br), iodine (I), and the like. By way of examples, the etchant can be or include one or more halogen gases, such as hydrogen chloride, F₂, Cl₂, Br₂, and I₂.

A temperature within the reaction chamber during step 110 can be about 800° C. to about 1250° C., about 950° C. to about 1200° C., about 950° C. to about 1100° C., or about 850° C. to about 1250° C.

A pressure within the reaction chamber during step 110 can be about 50 Torr to about 1 ATM, about 50 Torr to about 600 Torr, or about 200 Torr to about 500 Torr. A flowrate of an etchant during step 110 can be about 12 to about 22 standard liters per meter (SLM) or about 0.5 to about 30 SLM.

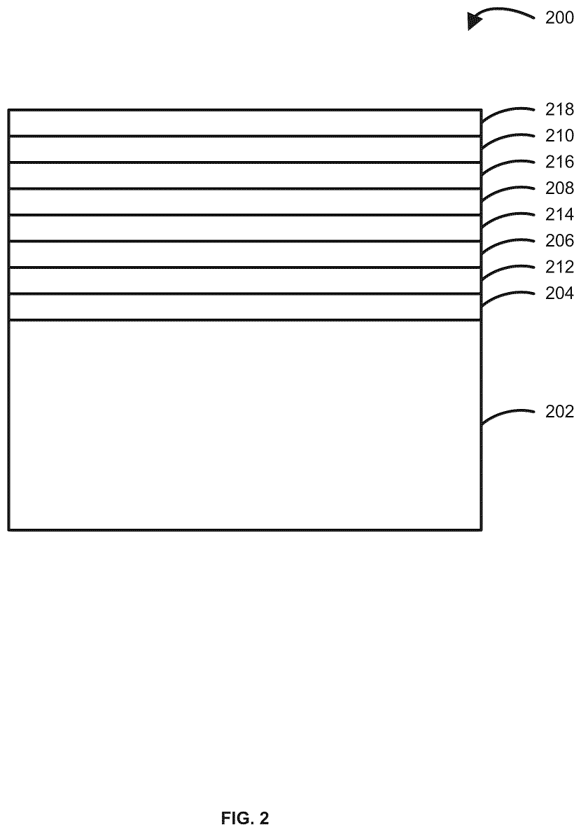

FIG. 2 illustrates a device structure (sometimes referred to simply as structure) 200 formed in accordance with exemplary embodiments of the disclosure. Structure 200 includes a substrate 202 and a plurality of epitaxial layers 204-218 formed overlying substrate 202. In particular, structure 200 include a plurality of epitaxial silicon germanium layers 204, 206, 208, and 210 alternating with a plurality of silicon layers 212, 214, 216, and 218. Epitaxial layers 204-218 can be formed, for example, during step 106 of method 100.

As noted above, a plurality of structures, such as structure 200, can be formed prior to performing a step of cleaning the reaction chamber. Further, using techniques described herein, within layer uniformity of film thickness and composition is improved, compared to performing a clean process after each substrate or step 106. Further, substrate-to-substrate composition and thickness uniformity is improved using techniques described herein, compared to methods that employ a clean after each substrate or step 106. And, layer-to-layer on a substrate (within stack) uniformity for both composition and thickness are improved compared to traditional methods.

With a typical deposition process, an oscillation in the apparent temperature can be detected by a pyrometer during deposition of a thin film on a substrate or directly onto the susceptor. The oscillation can be correlated with the growing film thickness and can be described using the Fresnel's equation for thin-film interference. By depositing a precoat as described herein, process throughput, total thermal budget, and precursor consumption for an epitaxial growth process can individually or collectively be improved.

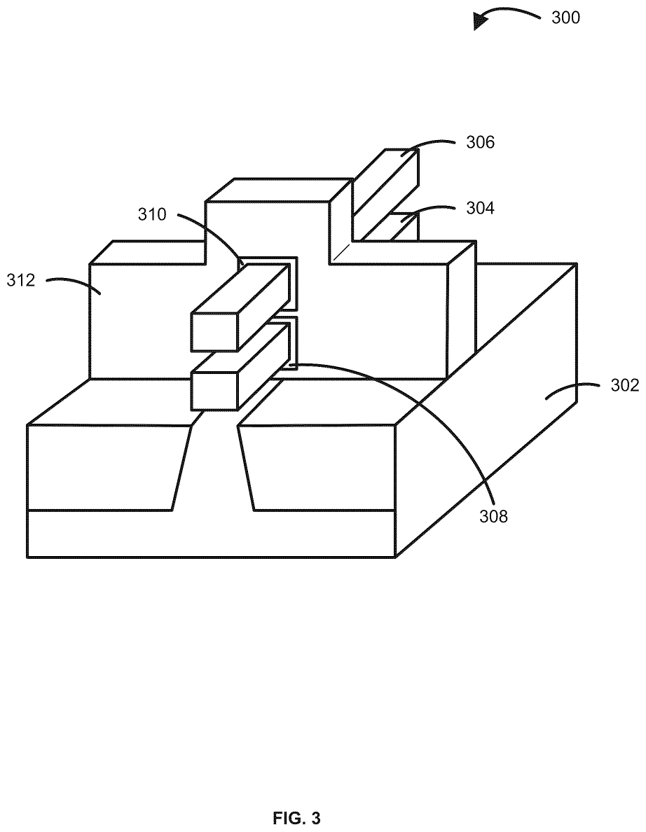

FIG. 3 illustrates a device structure (sometimes referred to simply as structure) 300 in accordance with further examples of the disclosure. Structure 300 can be used to form a gate all around field effect transistor. Structure 200 can be used to form structure 300 by etching the epitaxial silicon layers and removing the epitaxial silicon germanium layers.

Structure 300 includes a substrate 302, one or more silicon channel regions or nanowires 304, 306, dielectric material 308, 310, and a conducing material 312. Silicon channel regions or nanowires 304, 306 can be formed, for example, by forming epitaxial layers according to method 100.

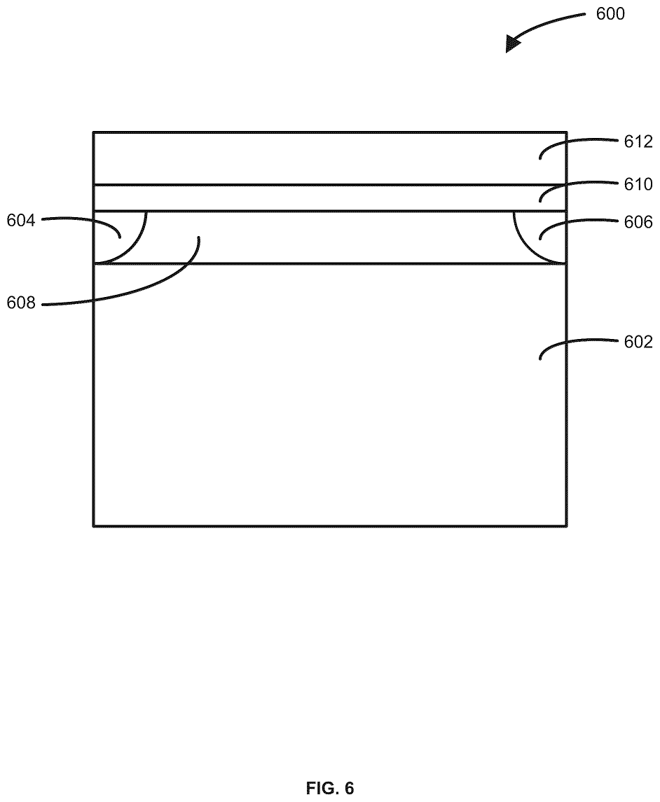

FIG. 6 illustrates another device structure 600 in accordance with examples of the disclosure. Device structure 600 is suitable for forming metal oxide semiconductor field effect transistors (MOSFET) (e.g., p-MOSFET) devices.

In the illustrative example, device structure 600 includes a substrate 602, a source region 604, a drain region 606, and a SiGe channel region 608 formed between source region 604 and drain region 606. SiGe channel region 608 can be formed on multiple substrates according to a method, such as method 100, described herein. In accordance with examples of the disclosure, a thickness of SiGe channel region 608 can be about 40 Angstroms to about 150 Angstroms or about 80 Angstroms to about 120 Angstroms or about 40 Angstroms to about 1000 Angstroms.

Device structure 600 also include a dielectric layer 610, such as silicon oxide and/or a metal oxide and conducting material 612, such as polysilicon and/or on or more metal layers.

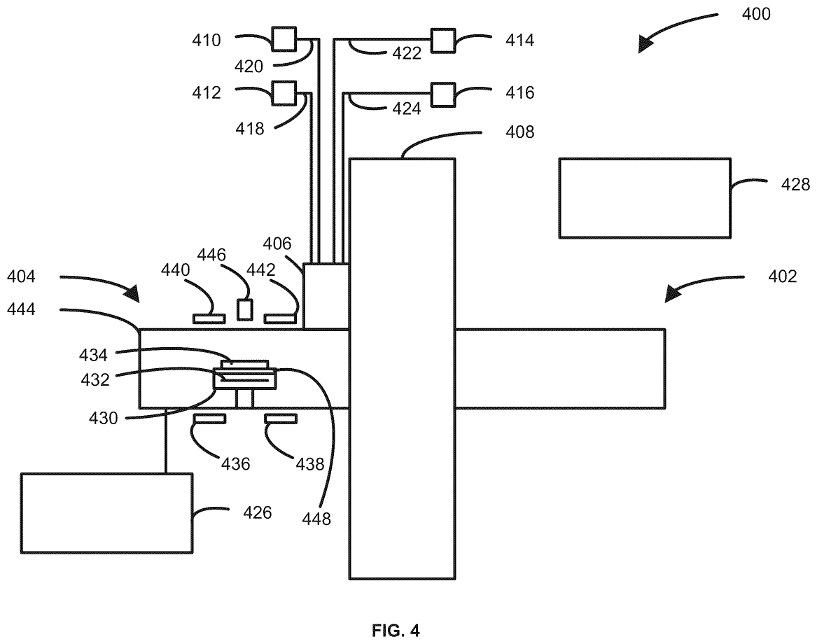

FIG. 4 illustrates an exemplary reactor system 400 in accordance with examples of the disclosure. Reactor system 400 can be used for a variety of applications, such as to perform method 100, to form structure 200, or the like.

In the illustrated example, reactor system 400 includes an optional substrate handling system 402, a reaction chamber 404, a gas injection system 406, and optionally a wall 408 disposed between reaction chamber 404 and substrate handling system 402. System 400 can also include a first gas source 410, a second gas source 412, a third gas source 414 and a fourth gas source 416, an exhaust source 426, a controller 428, and a susceptor or substrate support 430. Although illustrated with four gas sources 410-416, reactor system 400 can include any suitable number of gas sources. Further, reactor system 400 can include any suitable number of reaction chambers 404, which can each be coupled to a gas injection system 406. In the case in which reactor system 400 includes multiple reaction chambers, each gas injection system can be coupled to the same gas sources 410-416 or to different gas sources. Reactor system 400 can include any suitable number of substrate handling systems 402. Reaction chamber 404 of reactor system 400 can be or include, for example, a cross flow, cold wall epitaxial reaction chamber.

Gas sources 410-416 can include, for example, various combinations of one or more precursors, one or more dopant sources, one or more etchants, and mixtures of gases, including mixtures of one or more precursors, dopant sources, and/or etchants with one or more carrier gases.

By way of examples, first gas source 410 can include an etchant. Second gas source 412 can include a precursor. Exemplary etchants can include a halide, such as a chlorine-containing gas. Exemplary chlorine-containing gases include one or more gases selected from the group consisting of hydrogen chloride, chlorine gas, and the like.

Exemplary precursors include silicon-containing precursors, such as trichlorosilane, dichlorosilane, silane, disilane, trisilane, silicon tetrachloride, other silicon precursors noted herein, and the like.

In some cases, one or more gas sources can include a dopant. Exemplary dopant sources include gases that include one or more of As, P, C, Ge, and B. By way of examples, the dopant source can include germane, diborane, phosphine, arsine, or phosphorus trichloride.

One or more sources 410-416 can include a carrier and/or dilution gas, such as a carrier or dilution gas as described herein.

Susceptor or substrate support 430 can include one or more heaters 432 to heat a substrate 434 to a desired temperature, such as a temperature noted herein. Susceptor or substrate support 430 can also be configured to rotate (or not) during processing. In accordance with examples of the disclosure, susceptor or substrate support 430 rotates at a speed of about 60 to about 2, about 35 to about 2, or about 35 to about 15 rotations per minute.

Reactor system 400 can also include one or more lamps 436-442 to heat the substrate 434 and/or a wall (e.g., wall 444) of reaction chamber 404. In addition, reactor system 400 can include one or more pyrometers 446 to measure a temperature within reaction chamber 404.

As noted above, in accordance with various examples of the disclosure, prior to processing a substrate, such as substrate 434, reaction chamber 404 can be coated with a precoat material 448 using, for example, method steps as described herein.

Exhaust source 426 can include one or more vacuum pumps.

Controller 428 includes electronic circuitry and software to selectively operate valves, manifolds, heaters, pumps and other components included in the system 400. Such circuitry and components operate to introduce precursors, reactants, and purge gases from the respective sources 410-416. Controller 428 can control timing of gas pulse sequences, temperature of the substrate and/or reaction chamber, pressure within the reaction chamber, and various other operations to provide proper operation of the system 400. Controller 428 can include control software to electrically or pneumatically control valves to control flow of precursors, reactants and purge gases into and out of the reaction chamber 404. Controller 428 can include modules, such as a software or hardware component, e.g., a FPGA or ASIC, which performs certain tasks. A module can advantageously be configured to reside on the addressable storage medium of the control system and be configured to execute one or more processes.

During operation of reactor system 400, substrate 434 is transferred from, e.g., substrate handling system 402, to reaction chamber 404. Once substrate(s) 434 are transferred to reaction chamber 404, one or more gases from gas sources 410-416 are introduced into reaction chamber 404 via gas injection system 406. Gas injection system 406 can be used to meter and control gas flow of one or more gases from gas sources 410-416 during substrate processing and to provide desired flows of such gas(es) to multiple sites within reaction chamber 404.

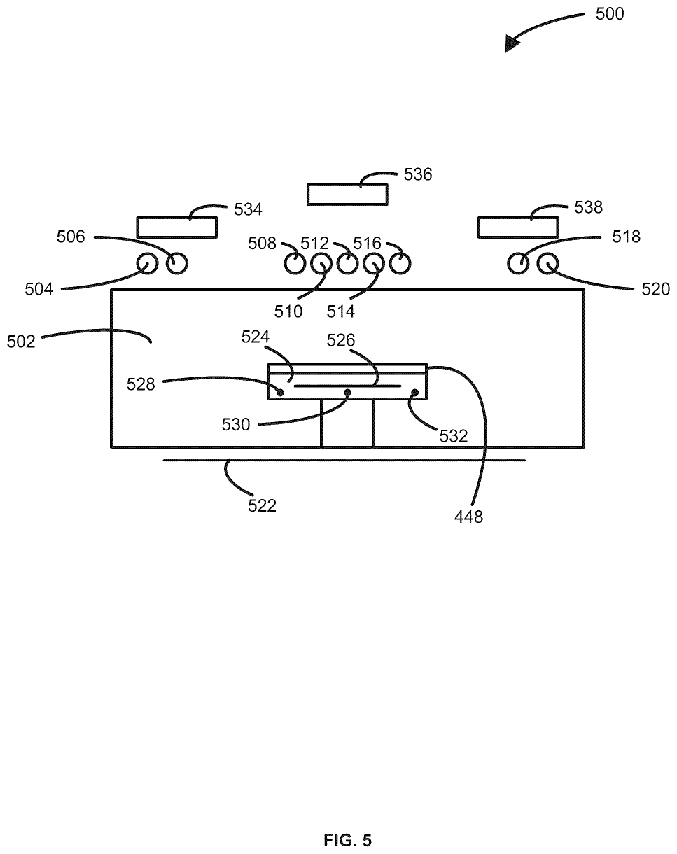

FIG. 5 illustrates another reactor system 500 in accordance with examples of the disclosure. Reactor 500 can be the same or similar to reactor system 400.

In the illustrated example, reactor system 500 includes a reaction chamber 502, heaters 504-522, a susceptor 524, a heating element 526, temperature sensors 528-532 (e.g., thermocouple or pyrometers), and temperature sensors 534-538 (e.g., thermocouple or pyrometers).

Reaction chamber 502 can be the same or similar to reaction chamber 404.

Heaters 504-522 can be or include, for example, (e.g., infrared) heating lamps. As illustrated, lamps 504-520 can be in a first direction and one or more lamps 522 can be in a (e.g., substantially perpendicular) second direction. Further, heaters 504-522 can be segmented into one or more heating zones. For example, heaters 504, 506 can be in a first (e.g., front) zone; heaters 508-516 and optionally heater 522 can be in a second (e.g., middle, i.e., center zone); and heaters 518, 520 can be in a third (e.g., rear) zone. Each zone can include one or more heaters and is not necessarily limited to the configuration illustrated. By way of examples, each zone can include from about 1 to about 24 or about 2 to about 16 heaters. In accordance with embodiments of the disclosure, a temperature within each zone can be independently controlled by measuring a temperature—e.g., using one or more temperature sensors 534-538 and using a controller, such as controller 428. Further, another heating element 526 on or embedded within susceptor 524 can be used to control a temperature of a substrate. Heating element 526 can be independently controlled of controlled in connection with one or more zones. Such independent temperature control can be used, for example, during one or more step of method 100. In accordance with particular examples, a reactor system can include about 1 to about 24 or about 2 to about 16 linear lamps (e.g., in one or more of the zones) and one or more spot lamps in in one or more zones. The linear lamps can be, for example, silicon-controlled rectifier (SCR) linear lamps. Each linear lamp can exhibit, for example, about 10,000 W maximum output. The spot lamps can each be formed of, for example, four individual round spots and can be located, for example, below the reaction chamber. The maximum capacity of each round spot can be about 1000-2000 W.

In accordance with examples of the disclosure, such as deposition of silicon germanium, at least two or at least three temperature zones are independently controlled—e.g., during a precoat deposition and/or during an epitaxial layer deposition process. By way of examples, a front (e.g., nearest the gas inlet) temperature zone can be controlled to a higher temperature (e.g., greater than 10° C. or greater than or about 25° C.) than the middle temperature zone, which can be higher than the rear temperature zone (e.g., less than 10° C. or less than or about 25° C. than a target middle zone temperature).

Although exemplary embodiments of the present disclosure are set forth herein, it should be appreciated that the disclosure is not so limited. For example, although the reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

1. A method of depositing at least two epitaxial material layers, the method comprising the steps of:
coating, via a pre-coating step, a surface of a reaction chamber of a reactor system with a precoat material;
after the pre-coating step, sequentially performing, via two or more substrate processing steps, substrate processing without performing the pre-coating step in between the two or more substrate processing steps, each of the two or more substrate processing steps comprising:
loading a substrate into the reaction chamber of the reactor system;
depositing a first epitaxial material layer on a surface of the substrate;
depositing a second epitaxial material layer on the first epitaxial material layer, wherein the second epitaxial material layer is different and distinct from the first epitaxial material layer; and
unloading a processed substrate from the reaction chamber;
after the two or more substrate processing steps, cleaning, via a cleaning step, the reaction chamber; and
after the cleaning the reaction chamber, repeating the pre-coating step and the two or more substrate processing steps prior to repeating the cleaning step.

2. The method of claim 1, wherein the cleaning step comprises a step of removing at least a portion of the precoat material.

3. The method of claim 1, wherein:
the precoat material comprises silicon, and
the precoat material comprises greater than 70 atomic percent silicon.

4. The method of claim 1, wherein the precoat material comprises silicon germanium.

5. The method of claim 1, wherein during the step of depositing the first epitaxial material layer on the surface of the substrate, a precursor comprising a halogen is provided to the reaction chamber.

6. The method of claim 1, wherein during the step of depositing the first epitaxial material layer on the surface of the substrate, an etchant is provided to the reaction chamber, and wherein the etchant comprises a halogen.

7. The method of claim 1, wherein during the step of depositing the first epitaxial material layer on the surface of the substrate, a precursor comprising one or more of germane and digermane is provided to the reaction chamber.

8. The method of claim 1, wherein a temperature within the reaction chamber during the step of depositing the first epitaxial material layer on a surface of the substrate is about 350° C. to about 950° C.

9. The method of claim 2, wherein a temperature within the reaction chamber during the step of cleaning is about 850° C. to about 1250° C.

10. The method of claim 1, wherein a thickness of the precoat material is between about 0.5 and about 20 microns.

11. The method of claim 1, wherein a thickness of the precoat material is between about 10 and about 5000 angstroms.

12. A method of forming a plurality of device structures, wherein each of the plurality of device structures is formed in response to performing the steps of the method of claim 1.

13. The method of claim 12, wherein the device structure includes one or more layers comprising silicon and one or more layers comprising silicon germanium.

14. The method of claim 12, wherein the device structure includes a plurality of layers comprising silicon and a plurality of layers comprising silicon germanium.

15. The method of claim 12, wherein the device structure is used to form a gate all around device.

16. The method of claim 1, wherein:
the loading the substrate into the reaction chamber further comprises disposing the substrate on a susceptor within the reaction chamber, and
the pre-coating step further comprises coating at least a portion of the susceptor with the precoat material.

17. The method of claim 1, further comprising a deposition step after the loading the substrate into the reaction chamber, the deposition step comprising alternating between the depositing the first epitaxial material layer and the depositing the second epitaxial material layer.

18. The method of claim 1, wherein the depositing the first epitaxial material layer or the depositing the second epitaxial material layer is deposited by flowing one or more precursors into the reaction chamber, the one or more precursors comprising at least one of a silicon halide and a silane.

19. The method of claim 1, wherein during the steps of depositing, temperatures of two or more zones within the reaction chamber are independently controlled.

20. A method of depositing at least two epitaxial material layers, the method comprising the steps of:
coating via a pre-coating step, a surface of a reaction chamber of a reactor system with a precoat material;
after the pre-coating step, sequentially performing, via two or more substrate processing steps, substrate processing without performing the pre-coating step in between the two or more substrate processing steps, each of the two or more substrate processing steps comprising:
loading a substrate into the reaction chamber of the reactor system;
depositing an epitaxial material layer on a surface of the substrate; and
unloading the substrate from the reaction chamber;
after the two or more substrate processing steps, cleaning, via a cleaning step, the reaction chamber; and
after the cleaning the reaction chamber, repeating the pre-coating step and the two or more substrate processing steps prior to repeating the cleaning step.
